(19) United States
(12) Patent Application Publication
(10) Pub. No.: US 2024/0282381 A1
(43) Pub. Date: Aug. 22, 2024

(54) HYBRID DYNAMIC WORD LINE START VOLTAGE

(71) Applicant: Micron Technology, Inc., Boise, ID (US)

(72) Inventors: Chun Sum Yeung, San Jose, CA (US); Kulachet Tanpairoj, San Mateo, CA (US); Deping He, Boise, ID (US)

(21) Appl. No.: 18/426,117

(22) Filed: Jan. 29, 2024

Related U.S. Application Data
(60) Provisional application No. 63/486,365, filed on Feb. 22, 2023.

(51) Int. Cl. G11C 16/10; G11C 16/08

(52) U.S. Cl. CPC G11C 16/102; G11C 16/08

(57) ABSTRACT

Methods, systems, and devices for hybrid DWLSV are described. One or more controllers may communicate one or more program commands to a NAND memory device. The memory device may perform program operations that correspond to the program commands communicated by the controller. The memory device may perform the program operations using a word line start voltage. Once the programming operations are complete, the memory device may communicate the lowest word line starting voltage offset associated with performing the program operations to the one or more controllers.

### CROSS REFERENCE

The present application for Patent claims priority to U.S. Patent Application No. 63/486,365 by Yeung et al., entitled “HYBRID DYNAMIC WORD LINE START VOLTAGE,” filed Feb. 22, 2023, which is assigned to the assignee hereof, and which is expressly incorporated by reference in its entirety herein.

### TECHNICAL FIELD

The following relates to one or more systems for memory, including aspects related to a hybrid dynamic word line start voltage (DWLSV).

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states if disconnected from an external power source.

### BRIEF DESCRIPTION OF THE DRAWINGS

FIG. 1 illustrates an example of a system that supports a hybrid DWLSV in accordance with examples as disclosed herein.

FIG. 2 illustrates an example of a system that supports a hybrid DWLSV in accordance with examples as disclosed herein.

FIG. 3 illustrates an example of a flowchart showing a method or methods that support a hybrid DWLSV in accordance with examples as disclosed herein.

FIG. 4 illustrates a block diagram of a memory system that supports a hybrid DWLSV in accordance with examples as disclosed herein.

FIGS. 5 and 6 illustrate flowcharts showing a method or methods that support a hybrid DWLSV in accordance with examples as disclosed herein.

### DETAILED DESCRIPTION

A dynamic word line start voltage (DWLSV) is a feature for some memory systems, such as NAND, that provides an ability to reduce a programming time associated with memory (tPROG). This may be accomplished by dynamically adjusting a programming starting voltage based on or in response to previous programming operations, thus improving system write performance based on using a more accurate programming starting voltage. After completing a programing operation, an offset word line voltage (which may be referred to as an offset voltage) may be stored and used for future programming. In some examples, the offset voltage may correspond to a differential voltage value relative to another DWLSV (e.g., a default DWLSV, an earlier DWLSV), which may be referred to as a default start voltage, used to program the memory, such as the NAND. The stored offset voltage reduces and/or prevents the need to initiate a subsequent programming operation from a very low voltage level and scale up (e.g., increase) the word line voltage until reaching an appropriate level. The process of scaling up the word line voltage may be time consuming and may slow down programming performance, among other issues.

In some other different examples, this offset voltage may be stored in the NAND in a process called auto-DWLSV. In such a process, the NAND automatically adjusts the starting voltage for the programming operation based on or in response to the block address. A disadvantage associated with auto-DWLSV is that the NAND has limited space and can only store offset voltages for a limited quantity of block addresses. Additional registers and circuitry are required on the NAND die to provide storage for additional offset voltages, among other disadvantages.

In some other different examples, values for the starting offset voltage are stored outside the NAND and retrieved at the start of a programming operation in a process called manual-DWLSV. Thus, manual-DWLSV may provide an ability to store the starting voltage offset of a greater number of block addresses. The stored voltage offsets may be managed by one or more components of the memory system, such as a NAND controller. However, a disadvantage of manual-DWLSV is the additional commands (steps) that must be communicated to retrieve offset voltage after completing a program operation and communicate the offset voltage to the NAND before the next program operation, among other disadvantages.

The memory system may have several methods to program the blocks, namely 1 single block program, 2 multi-plane block program, 4 multi-plane block program, etc. The memory system may also have different open blocks for different block types (e.g., static, dynamic, high endurance, etc.). Furthermore, the memory system frequently performs programming operations on block stripes (which may be referred to as super blocks having groups of blocks such as eight block), and therefore must issue several commands to retrieve the offset voltage for every block type in the block stripe. Once the offset voltage of all blocks from the same block stripe have been retrieved, the memory system may calculate the optimized starting word line voltage. The limited quantity of offset voltages that may be stored in the NAND die using auto-DWLSV, or the quantity of commands required between the system and NAND to retrieve the offset voltages using manual-DWLSV, can adversely affect system performance, among other disadvantages.

According to the disclosed examples, a hybrid-DWLSV is described. The hybrid-DWLSV relates to management of the DWLSV task by division into two sub-tasks. In the first sub-task, a component, such as the NAND die, determines a DWLSV (e.g., a lowest DWLSV) for a block. In the second sub-task, the DWLSV offsets (e.g., the lowest DWLSV offsets) are stored according to block types within the memory system, e.g., by the NAND controller or other external component. In some examples, the NAND may compare a word line voltage associated with a word line each time there is a change, and provide the lowest offset voltage according to a block type, regardless of the quantity of blocks being programmed. In some examples, the system may store the offset voltage of a block type (or block types) and provide the offset voltage for use, at least in part, as starting word line voltage value(s) before issuing program commands to the NAND. In some examples, the system (e.g., NAND controller) may issue a “set_feature” command to provide an offset voltage to the NAND, and/or a “get_feature” command to retrieve the offset voltage for the current block type from the NAND. The current offset voltage may be retrieved before switching to another block type in some examples.

According to disclosed examples, complexities associated with increasing the size of the NAND die to store additional offset voltages (e.g., by adding registers, circuitry, etc.) for other different techniques may be reduced and/or eliminated. Furthermore, delays associated with exchanging signals and commands between the NAND die and system to store and retrieve offset voltages externally for other different techniques may be reduced and/or eliminated. Accordingly, the programming time (e.g., tPROG) for the NAND may be reduced, and firmware overhead and overall system performance may be improved, among other advantages.

In addition to applicability in memory systems as described herein, techniques for a hybrid dynamic word line start voltage may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by more efficient programming time associated with memory, among other benefits.

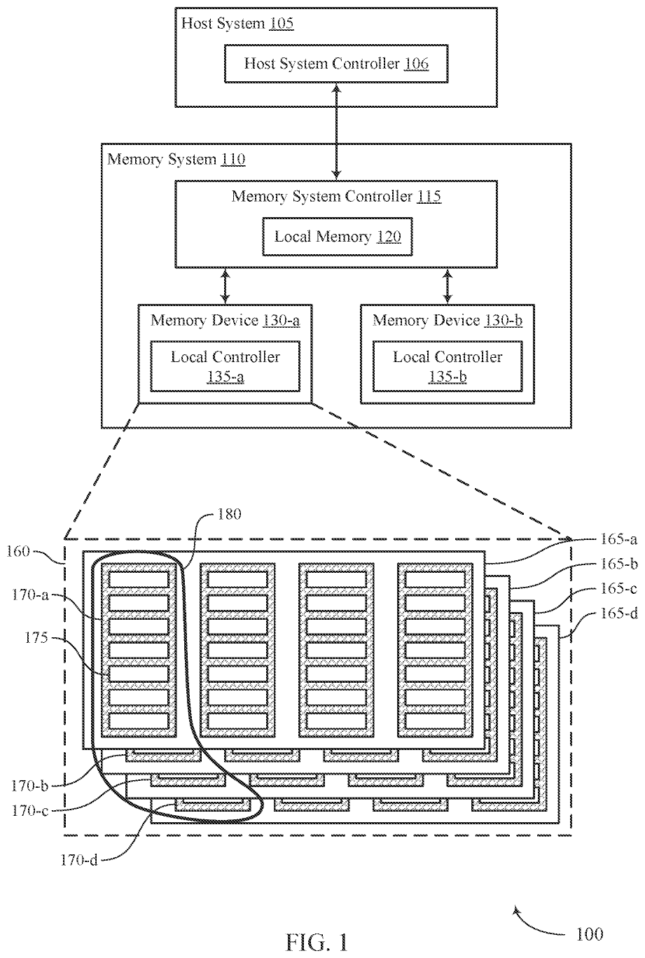

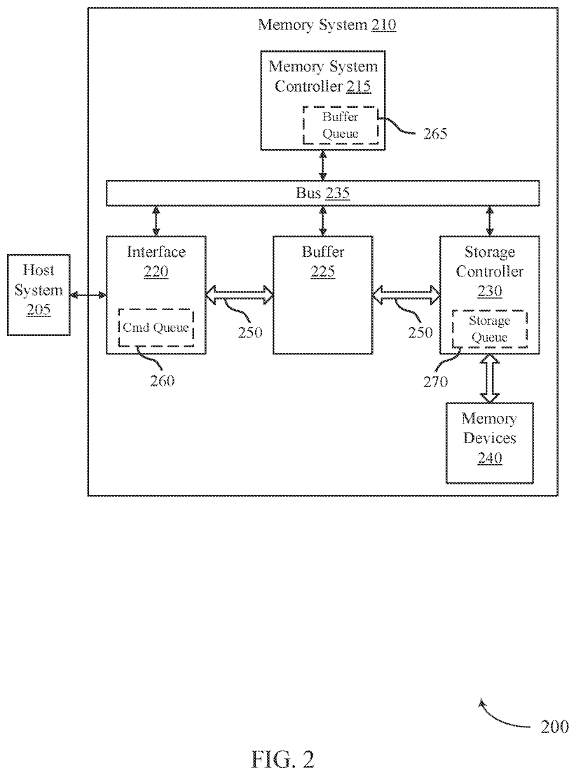

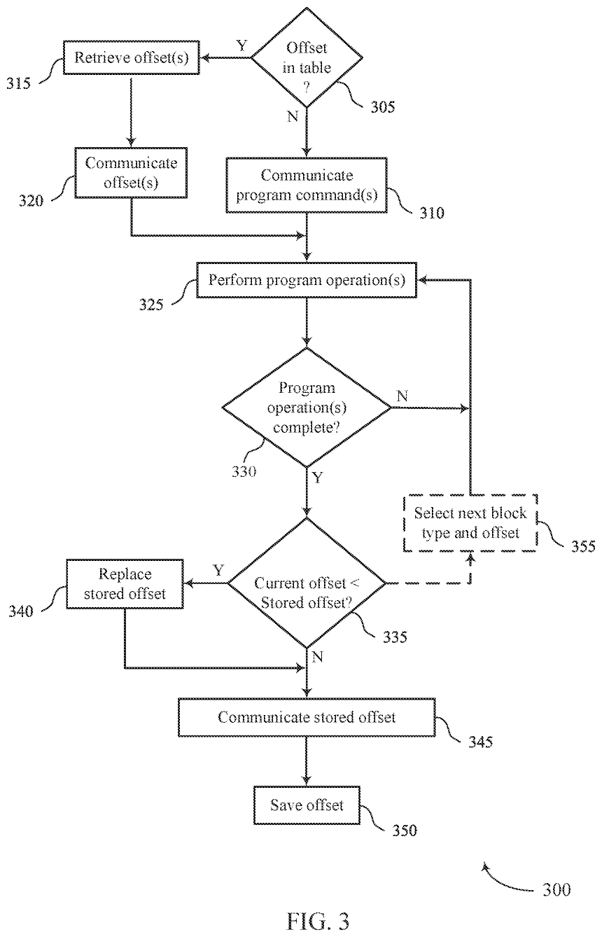

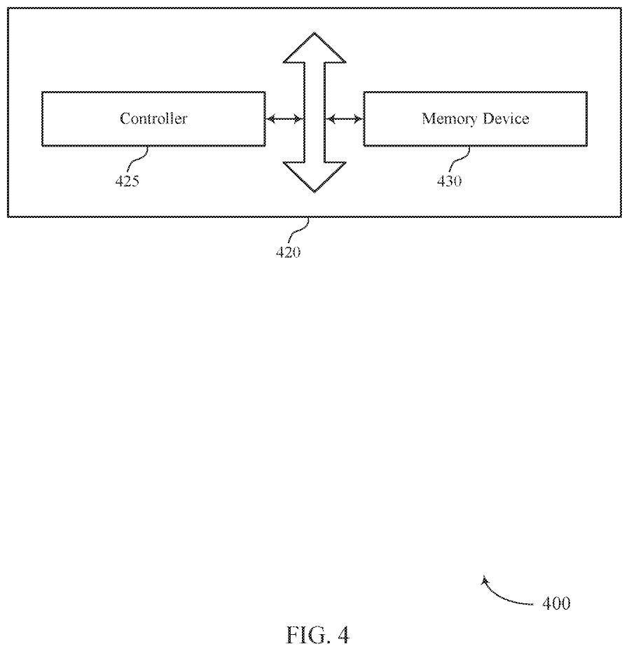

Features of the disclosure are initially described in the context of systems, devices, and circuits with reference to FIGS. 1 through 2. Features of the disclosure are described in the context of a flowchart illustrating a method that supports hybrid DWLSV with reference to FIG. 3. These and other features of the disclosure are further illustrated by and described in the context of an apparatus diagram and flowcharts that relate to hybrid DWLSV with reference to FIGS. 4 through 6.

FIG. 1 illustrates an example of a system 100 that supports hybrid DWLSV in accordance with examples as disclosed herein. The system 100 includes a host system 105 coupled with a memory system 110.

A memory system 110 may be or include any device or collection of devices, where the device or collection of devices includes at least one memory array. For example, a memory system 110 may be or include a Universal Flash Storage (UFS) device, an embedded Multi-Media controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other possibilities.

The system 100 may be included in a computing device such as a desktop computer, a laptop computer, a network server, a mobile device, a vehicle (e.g., airplane, drone, train, automobile, or other conveyance), an Internet of Things (IoT) enabled device, an embedded computer (e.g., one included in a vehicle, industrial equipment, or a networked commercial device), or any other computing device that includes memory and a processing device.

The system 100 may include a host system 105, which may be coupled with the memory system 110. In some examples, this coupling may include an interface with one or more host system controllers 106, which may be an example of a controller or control component configured to cause the host system 105 to perform various operations in accordance with examples as described herein. The host system 105 may include one or more devices and, in some cases, may include one or more processor chipsets and a software stack executed by the one or more processor chipsets. For example, the host system 105 may include an application configured for communicating with the memory system 110 or a device therein. The processor chipset may include one or more cores, one or more caches (e.g., memory local to or included in the host system 105), one or more memory controllers (e.g., NVDIMM controller), and one or more storage protocol controllers (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between one or more host system controllers 106 of the host system 105 and one or more memory system controllers 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations—which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 (e.g., one or more memory system controllers 115) may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (RAM) (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on a same die or within a same package) one or more local controllers 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170, and in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in a same page 175 may share (e.g., be coupled with) a common word line, and memory cells in a same string may share (e.g., be coupled with) a common digit line (which may alternatively be referred to as a bit line).

For some NAND architectures, memory cells may be read and programmed (e.g., written) at a first level of granularity (e.g., at the page level of granularity) but may be erased at a second level of granularity (e.g., at the block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

The system 100 may include any quantity of non-transitory computer readable media that support hybrid DWLSV. For example, the host system 105 (e.g., one or more host system controllers 106), the memory system 110 (e.g., one or more memory system controllers 115), or a memory device 130 (e.g., a local controller 135) may include or otherwise may access one or more non-transitory computer readable media, among other locations, storing instructions (e.g., firmware, logic, code) for performing the functions described herein to a host system (e.g., the host system 105), a memory system (e.g., the memory system 110), or a memory device (e.g., a memory device 130), or any combination thereof. For example, such instructions, if executed by the host system 105 (e.g., by a host system controller 106), by the memory system 110 (e.g., by a memory system controller 115), or by a memory device 130 (e.g., by a local controller 135), or any combination thereof, may cause the host system 105, the memory system 110, or the memory device 130 to perform associated functions as described herein.

In some examples, one or more controllers such as local controller 135-a may communicate one or more program commands to a memory device, such as a NAND memory device 130-a. The memory device 130-a may perform program operations that correspond to program commands that have been communicated by the controller 135-a. The memory device 130-a may perform the program operations using a word line start voltage. Once the programming operations are complete, the memory device 130-a may communicate the lowest word line starting voltage offset associated with performing the one or more program operations to the controller 135-a.

FIG. 2 illustrates an example of a system 200 that supports hybrid DWLSV in accordance with examples as disclosed herein. The system 200 may be an example of a system 100 as described with reference to FIG. 1, or aspects thereof. The system 200 may include a memory system 210 configured to store data received from the host system 205 and to send data to the host system 205, if requested by the host system 205 using access commands (e.g., read commands or write commands). The system 200 may implement aspects of the system 100 as described with reference to FIG. 1. For example, the memory system 210 and the host system 205 may be examples of the memory system 110 and the host system 105, respectively.

The memory system 210 may include one or more memory devices 240 to store data transferred between the memory system 210 and the host system 205 (e.g., in response to receiving access commands from the host system 205). The memory devices 240 may include one or more memory devices as described with reference to FIG. 1. For example, the memory devices 240 may include NAND memory, PCM, self-selecting memory, 3D cross point or other chalcogenide-based memories, FERAM, MRAM, NOR (e.g., NOR flash) memory, STT-MRAM, CBRAM, RRAM, or OxRAM, among other examples.

The memory system 210 may include a storage controller 230 for controlling the passing of data directly to and from the memory devices 240 (e.g., for storing data, for retrieving data, for determining memory locations in which to store data and from which to retrieve data). The storage controller 230 may communicate with memory devices 240 directly or via a bus (not shown), which may include using a protocol specific to each type of memory device 240. In some cases, a single storage controller 230 may be used to control multiple memory devices 240 of the same or different types. In some cases, the memory system 210 may include multiple storage controllers 230 (e.g., a different storage controller 230 for each type of memory device 240). In some cases, a storage controller 230 may implement aspects of a local controller 135 as described with reference to FIG. 1.

The memory system 210 may include an interface 220 for communication with the host system 205, and a buffer 225 for temporary storage of data being transferred between the host system 205 and the memory devices 240. The interface 220, buffer 225, and storage controller 230 may support translating data between the host system 205 and the memory devices 240 (e.g., as shown by a data path 250), and may be collectively referred to as data path components.

Using the buffer 225 to temporarily store data during transfers may allow data to be buffered while commands are being processed, which may reduce latency between commands and may support arbitrary data sizes associated with commands. This may also allow bursts of commands to be handled, and the buffered data may be stored, or transmitted, or both (e.g., after a burst has stopped). The buffer 225 may include relatively fast memory (e.g., some types of volatile memory, such as SRAM or DRAM), or hardware accelerators, or both to allow fast storage and retrieval of data to and from the buffer 225. The buffer 225 may include data path switching components for bi-directional data transfer between the buffer 225 and other components.

The memory system 210 also may include a memory system controller 215 for executing the commands received from the host system 205, which may include controlling the data path components for the moving of the data. The memory system controller 215 may be an example of the memory system controller 115 as described with reference to FIG. 1. A bus 235 may be used to communicate between the system components.

In some cases, one or more queues (e.g., a command queue 260, a buffer queue 265, a storage queue 270) may be used to control the processing of access commands and the movement of corresponding data. This may be beneficial, for example, if more than one access command from the host system 205 is processed concurrently by the memory system 210. The command queue 260, buffer queue 265, and storage queue 270 are depicted at the interface 220, memory system controller 215, and storage controller 230, respectively, as examples of a possible implementation. However, queues, if implemented, may be positioned anywhere within the memory system 210.

Data transferred between the host system 205 and the memory devices 240 may be conveyed along a different path in the memory system 210 than non-data information (e.g., commands, status information). For example, the system components in the memory system 210 may communicate with each other using a bus 235, while the data may use the data path 250 through the data path components instead of the bus 235. The memory system controller 215 may control how and if data is transferred between the host system 205 and the memory devices 240 by communicating with the data path components over the bus 235 (e.g., using a protocol specific to the memory system 210).

If a host system 205 transmits access commands to the memory system 210, the commands may be received by the interface 220 (e.g., according to a protocol, such as a UFS protocol or an eMMC protocol). Thus, the interface 220 may be considered a front end of the memory system 210. After receipt of each access command, the interface 220 may communicate the command to the memory system controller 215 (e.g., via the bus 235). In some cases, each command may be added to a command queue 260 by the interface 220 to communicate the command to the memory system controller 215.

The memory system controller 215 may determine that an access command has been received based on or in response to the communication from the interface 220. In some cases, the memory system controller 215 may determine the access command has been received by retrieving the command from the command queue 260. The command may be removed from the command queue 260 after it has been retrieved (e.g., by the memory system controller 215). In some cases, the memory system controller 215 may cause the interface 220 (e.g., via the bus 235) to remove the command from the command queue 260.

After a determination that an access command has been received, the memory system controller 215 may execute the access command. For a read command, this may include obtaining data from one or more memory devices 240 and transmitting the data to the host system 205. For a write command, this may include receiving data from the host system 205 and moving the data to one or more memory devices 240. In either case, the memory system controller 215 may use the buffer 225 for, among other things, temporary storage of the data being received from or sent to the host system 205. The buffer 225 may be considered a middle end of the memory system 210. In some cases, buffer address management (e.g., pointers to address locations in the buffer 225) may be performed by hardware (e.g., dedicated circuits) in the interface 220, buffer 225, or storage controller 230.

To process a write command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the write command.

If the buffer 225 has sufficient space to store the write data, the memory system controller 215 may cause the interface 220 to transmit an indication of availability to the host system 205 (e.g., a “ready to transfer” indication), which may be performed in accordance with a protocol (e.g., a UFS protocol, an eMMC protocol). As the interface 220 receives the data associated with the write command from the host system 205, the interface 220 may transfer the data to the buffer 225 for temporary storage using the data path 250. In some cases, the interface 220 may obtain (e.g., from the buffer 225, from a buffer queue 265) the location within the buffer 225 to store the data. The interface 220 may indicate to the memory system controller 215 (e.g., via the bus 235) if the data transfer to the buffer 225 has been completed.

After the write data has been stored in the buffer 225 by the interface 220, the data may be transferred out of the buffer 225 and stored in a memory device 240, which may involve operations of the storage controller 230. For example, the memory system controller 215 may cause the storage controller 230 to retrieve the data from the buffer 225 using the data path 250 and transfer the data to a memory device 240. The storage controller 230 may be considered a back end of the memory system 210. The storage controller 230 may indicate to the memory system controller 215 (e.g., via the bus 235) that the data transfer to one or more memory devices 240 has been completed.

To process a read command received from the host system 205, the memory system controller 215 may determine if the buffer 225 has sufficient available space to store the data associated with the command. For example, the memory system controller 215 may determine (e.g., via firmware, via controller firmware), an amount of space within the buffer 225 that may be available to store data associated with the read command.

In some cases, the buffer queue 265 may support buffer storage of data associated with read commands in a similar manner as discussed with respect to write commands. For example, if the buffer 225 has sufficient space to store the read data, the memory system controller 215 may cause the storage controller 230 to retrieve the data associated with the read command from a memory device 240 and store the data in the buffer 225 for temporary storage using the data path 250. The storage controller 230 may indicate to the memory system controller 215 (e.g., via the bus 235) if the data transfer to the buffer 225 has been completed.

In some cases, the storage queue 270 may be used to aid with the transfer of read data. For example, the memory system controller 215 may push the read command to the storage queue 270 for processing. In some cases, the storage controller 230 may obtain (e.g., from the buffer 225, from the storage queue 270) the location within one or more memory devices 240 from which to retrieve the data. In some cases, the storage controller 230 may obtain (e.g., from the buffer queue 265) the location within the buffer 225 to store the data. In some cases, the storage controller 230 may obtain (e.g., from the storage queue 270) the location within the buffer 225 to store the data. In some cases, the memory system controller 215 may move the command processed by the storage queue 270 back to the command queue 260.

Once the data has been stored in the buffer 225 by the storage controller 230, the data may be transferred from the buffer 225 and sent to the host system 205. For example, the memory system controller 215 may cause the interface 220 to retrieve the data from the buffer 225 using the data path 250 and transmit the data to the host system 205 (e.g., according to a protocol, such as a UFS protocol or an eMMC protocol). For example, the interface 220 may process the command from the command queue 260 and may indicate to the memory system controller 215 (e.g., via the bus 235) that the data transmission to the host system 205 has been completed.

The memory system controller 215 may execute received commands according to an order (e.g., a first-in-first-out order, according to the order of the command queue 260). For each command, the memory system controller 215 may cause data corresponding to the command to be moved into and out of the buffer 225, as discussed herein. As the data is moved into and stored within the buffer 225, the command may remain in the buffer queue 265. A command may be removed from the buffer queue 265 (e.g., by the memory system controller 215) if the processing of the command has been completed (e.g., if data corresponding to the access command has been transferred out of the buffer 225). If a command is removed from the buffer queue 265, the address previously storing the data associated with that command may be available to store data associated with a new command.

In some examples, the memory system controller 215 may be configured for operations associated with one or more memory devices 240. For example, the memory system controller 215 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., LBAs) associated with commands from the host system 205 and physical addresses (e.g., physical block addresses) associated with memory cells within the memory devices 240. For example, the host system 205 may issue commands indicating one or more LBAs and the memory system controller 215 may identify one or more physical block addresses indicated by the LBAs. In some cases, one or more contiguous LBAs may correspond to noncontiguous physical block addresses. In some cases, the storage controller 230 may be configured to perform one or more of the described operations in conjunction with or instead of the memory system controller 215. In some cases, the memory system controller 215 may perform the functions of the storage controller 230 and the storage controller 230 may be omitted.

In some examples, a controller such as storage controller 230 may communicate one or more program commands to a memory device such as NAND memory device 240. In other examples, the program commands may be communicated by memory system controller 215. The memory device 240 may perform program operations that correspond to program commands that have been communicated by the storage controller 230 or the memory system controller 215. The memory device 240 may perform the program operations using a word line start voltage. Once the programming operations are complete, the memory device 240 may communicate the lowest word line starting voltage offset associated with performing the one or more program operations to the storage controller 230 or the memory system controller 215.

FIG. 3 illustrates an example of a flowchart 300 that supports hybrid DWLSV in accordance with examples as disclosed herein. According to the disclosed examples, a DWLSV operation may be distributed into two parts for the memory system that includes, at least in part, a memory controller and a memory device. One part of the DWLSV operation may be performed by the memory controller, while the other part of the DWLSV operation may be performed by the memory device. The memory controller may receive one program command or multiple program commands that provide an indication of operations to be performed on the memory device. According to some examples, the one or more program commands may be received from an external source such as a host device. According to other examples, the one or more program commands may be received from a controller associated with the memory system.

In some examples, the memory system may include a memory device such as memory device 130 and/or memory device 240, and a memory controller such as memory system controller 115, memory controller 135, and/or memory controller 215. In various examples, the memory device may include different types of memories such as NAND memory, PCM, self-selecting memory, 3D cross point or other chalcogenide-based memories, FERAM, MRAM, NOR (e.g., NOR flash) memory, STT-MRAM, CBRAM, RRAM, OxRAM, etc. The memory device may be used, for example, to store and provide access to various types of information. In some examples, the memory controller may communicate with the memory using a direct interface. In other examples, the memory controller may communicate with the memory device using a bus provided within the memory system. The memory controller may communicate with external devices, such as a host controller of a host system, in order to manage access operations associated with the memory device. Such access operations can include, for example, reading data, writing data, erasing data, or refreshing data at a memory device, such as memory device 130.

At 305, it may be determined whether an offset voltage is available for program operations associated with a memory device. In some examples, the host system or host controller may communicate instructions (or commands) to the memory controller for performing program operations such as storing and/or accessing information associated with the memory device. Upon receiving the commands, the memory controller may access a local storage component to determine whether an offset voltage is available for the received command. In some examples, the memory system may include an offset table that may be accessed by the memory controller. The offset table may store values representative of different offset voltages associated with program operations for the memory device. In some examples, the offset table may contain an offset voltage for every type of block within the memory device and/or every type of block that can be configured within the memory device. For example, each plane of the memory die of the memory device may include one or more of static, dynamic, and high endurance block types. The different block types may further be configured as SLC, TLC, MLC, and QLC.

According to some examples, the offset table may store a value for the voltage corresponding to a type of block, as well as information sufficient for identifying the block type. The offset table, therefore, may be configured as a 2-dimensional array. Entries in the offset table may be rearranged depending on various factors such as system performance, the types of commands received from the host controller, etc. At an instance in time, for example, the first three rows in the offset table may respectively correspond to a static SLC block, dynamic TLC block, and high endurance QLC block. At another instance, the first three rows may be rearranged as a high endurance QLC block, static SLC block, and dynamic TLC block, respectively. In other examples, the offset table may contain one dimension (or column), wherein each row is predefined for a particular type of block. Entries in such tables are fixed and always correspond to the same respective block types.

In some examples, the offset table may be stored within a non-volatile storage area of the memory system. Accordingly, the values stored within the offset table may be maintained during a total power loss or power cycling to the memory system. According to some examples, the memory controller may be configured to store offset voltage values for different block types in an external storage device. The external storage device may be associated with the host system.

If the memory controller identifies an offset voltage for the received command at 305, then the offset voltage may be retrieved from the offset table at 315. In some examples, the commands received by the memory controller may be associated with a single block type (e.g., static TLC) within the memory device. In such examples, the memory controller may retrieve one value for the offset voltage corresponding to the relevant block type (i.e., static TLC). In some examples, the commands received by the memory controller may be associated with multiple block types (e.g., static TLC, static QLC, high endurance SLC) within the memory device. In these examples, the memory controller may retrieve multiple offset voltages corresponding to the quantity of different block types.

At 320, the retrieved offset voltages may be communicated. For example, the memory controller may communicate the retrieved offset voltages, for example, to the memory device. In some examples, the memory controller may issue a function command to perform the operation of communicating the offset voltages. The memory controller may issue, for example, a “set_feature” command to the memory device in order to communicate a different offset voltage value. In some examples, the memory controller may communicate multiple offset voltages to the memory device (e.g., individually, concurrently, sequentially) if the received commands are associated with multiple block types. If the memory controller does not detect an offset voltage for the received command within the offset table, then the memory controller may communicate (or issue) the received programming commands to the memory device. Accordingly, the memory device may receive one or more program commands from the memory controller with corresponding offset voltages. The memory device may also receive merely program commands, for example, without any offset voltages. For example, the memory controller may simply issue one or more program commands to the memory device at 310 if an offset voltage is not detected for the block type within the offset table at 305. If the memory controller detects an offset voltage for the block type associated with the command, then the memory controller may communicate both the program command and the offset voltage to the memory device.

At 325, the program operations corresponding to the received program commands may be performed, for example by a memory device. The program operations may include, for example, write, erase, read, etc. According to some examples, the memory device may be configured to perform program operations using a default voltage value as the DWLSV (e.g., default start voltage). More particularly, if the memory controller does not detect an offset voltage within the offset table, then the memory controller may communicate the program commands without an offset voltage. The memory device may then use the default start voltage to perform the program operations. In other examples, the memory device may receive the program commands together with an offset voltage. The memory device may, in some examples, combine the received offset voltage with the default start voltage in order to obtain the DWLSV for performing the program operations on the appropriate block type. In other examples, the offset table may store DWLSV values for different block types. The memory device may perform the program operations using the received command and DWLSV value for the block type.

The memory device may vary (increase or decrease) the program voltage used to perform the program operation until completion. If a program command requires programming operations (e.g., a write operation) on four pages of an eight-page block, the memory device may vary the voltage each time one of the pages is programmed.

At 330, it may be determined if the programming operation is complete, for example, by the memory device or the memory controller. If the programming operation is not complete (e.g., only two pages of X pages have been programmed), then control returns to 325 and the programming operation continues for the next page. For example, when programming for page three of an eight-page block is complete, the determination at 330 would result return to 325. The programming operation would continue, at 325, for page four (i.e., the next page) of the eight-page block. If it is determined that the programming operations have been completed, then the memory device may compare the current offset voltage to a stored offset voltage at 335. For example, when the programming operation for page eight of the eight-page block is complete, the determination at 330 would result in control passing to 335. The memory device may obtain the current offset voltage based, at least in part, on the current (or final) program voltage and the default start voltage.

In some examples, the stored offset voltage may be retained (e.g., stored) within a volatile storage location in the memory system such as a register. The register may store a value, such as a value of zero at start up, or in the event of a power outage. During programming operations, the memory device may store different values, from the value, in the register. As previously discussed, the memory system may vary the programming voltage used until the programming operation is completed. If the current offset voltage is determined to be less than the stored offset voltage, then the value of the stored offset voltage may be replaced with the current offset voltage at 340, for example, by the memory device or the memory controller. If the current offset voltage is greater than the stored offset voltage, then the memory system may maintain the current value for the stored offset voltage.

At 345, the stored offset voltage may be communicated, for example, to the memory controller. The stored offset voltage may correspond to the lowest program voltage for a given block type. According to some examples, the memory device may be configured to communicate an indication of completion once the program operation is complete. The indication of completion may be received (e.g., directly, indirectly) by the memory controller from the memory device. Upon receiving the indication of completion, the memory controller may be configured to issue a command to retrieve the offset voltage value stored, for example, within the register of the memory device. In at least some examples, the memory controller may be configured to issue a command (e.g., “get_feature”) to access the contents of the register containing the offset voltage. Upon receiving the command, the memory device may provide access to the contents of the register.

At 350, the offset voltage value may be stored within the offset table, for example by the memory controller. The offset voltage may be stored with an indication of the associated block type. The memory controller may further replace any previous offset voltage for the block type with the newly retrieved offset voltage for the same block type. In other examples, the offset table may contain predefined index locations associated with each particular block type. In such examples, the memory controller may store the new offset value within the indexed location corresponding to the block type.

According to at least some examples, multiple blocks or planes may be programmed concurrently (e.g., at least partially overlapping) and/or simultaneously. The blocks may be programmed as block stripes (or super blocks), which may contain a group of eight blocks in some examples. In such examples, the memory controller may communicate multiple offset voltage values at 320. The memory device may be configured to store a voltage value corresponding to each block type in different locations. The memory device may sequentially perform program operations on a first block type using the first offset voltage, and select the next offset voltage upon detecting that the program operations may be performed on a different block type. In such examples, the comparison performed at 335 may correspond to the current block type on which program operations have been completed. Accordingly, at 355, the next block type may be selected, for example by the memory device, and an associated offset voltage to perform the next programming operation may be selected, for example by the memory device. The programming operations may then resume at 325. Furthermore, each time the programming operations for a particular block type is complete, the memory device or another component of the memory system may provide an indication of completion so that the stored offset voltage may be communicated to the memory controller. If a block stripe containing eight blocks is being programmed, then steps 325, 330, and 335 may be repeated (e.g., iteratively performed) multiple times. An offset voltage may be saved for each different block type within the block stripe. The programming operation can be completed once all the blocks in the block stripe have been programmed.

Aspects of the process flow 300 may be implemented by one or more memory controllers and/or one or more memory devices, among other components. Additionally or alternatively, aspects of the process flow 300 may be implemented as instructions stored in memory (e.g., firmware stored in a memory coupled with memory system controller 115, local controller 135, memory system controller 215, and/or storage controller 230). For example, the instructions, if executed by a controller (e.g., the memory system controller 115 or the memory system controller 215), may cause the controller to perform the operations of the process flow 300.

FIG. 4 illustrates a block diagram 400 of a memory system 420 that supports hybrid DWLSV in accordance with examples as disclosed herein. The memory system 420 may be an example of aspects of a memory system as described with reference to FIGS. 1 through 3. The memory system 420, or various components thereof, may be an example of means for performing various aspects of hybrid DWLSV as described herein. For example, the memory system 420 may include a controller 425 a memory device 430, or any combination thereof. Each of these components may communicate, directly or indirectly, with one another (e.g., via one or more buses).

The controller 425 may be configured as or otherwise support a means for communicating, from a controller to a memory device, one or more program commands. The memory device 430 may be configured as or otherwise support a means for performing one or more program operations at the memory device using a word line start voltage based at least in part on communicating the one or more program commands. In some examples, the memory device 430 may be configured as or otherwise support a means for communicating a lowest word line starting voltage offset associated with performing the one or more program operations to the controller.

In some examples, the controller 425 may be configured as or otherwise support a means for determining whether a voltage offset exists for a block type associated with the one or more program commands. In some examples, the controller 425 may be configured as or otherwise support a means for communicating the one or more program commands including communicating a command indicating the voltage offset. In some examples, the word line start voltage is based, at least in part, on communicating the command indicating the voltage offset. In some examples, the word line start voltage is based, at least in part, on communicating the command indicating the voltage offset and a default voltage. In some examples, the word line start voltage is based, at least in part, on a default voltage.

In some examples, a plurality of block types are associated with the one or more program commands, and the controller 425 may be configured as or otherwise support a means for determining whether a voltage offset exists for each block type associated with the one or more program commands. In some examples, a plurality of block types are associated with the one or more program commands, and the controller 425 may be configured as or otherwise support a means for communicating one or more commands including communicating a command indicating a voltage offset for each block type based at least in part on determining that the voltage offset exists for the block type.

In some examples, the memory device 430 may be configured as or otherwise support a means for storing a word line start voltage offset for a first page of a block type associated with the one or more program commands. In some examples, the memory device 430 may be configured as or otherwise support a means for comparing the stored word line start voltage offset to a subsequent word line start voltage offset associated with a subsequent page of the block type. In some examples, the memory device 430 may be configured as or otherwise support a means for replacing the stored word line start voltage offset with the subsequent word line start voltage offset if the subsequent word line start voltage offset is less than the stored word line start voltage offset.

In some examples, the memory device 430 may be configured as or otherwise support a means for repeating the comparing and the replacing, until the one or more program operations have been performed on all pages of the block type. In some examples, the memory device 430 may be configured as or otherwise support a means for communicating an indication that the one or more program operations are complete to the controller.

In some examples, to support communicating the lowest word line start voltage offset, the memory device 430 may be configured as or otherwise support a means for communicating an indication that the program operation is complete to the controller. In some examples, to support communicating the lowest word line start voltage offset, the memory device 430 may be configured as or otherwise support a means for communicating the lowest word line start voltage offset in response to receiving a command from the controller. In some examples, the controller 425 may be configured as or otherwise support a means for storing the lowest word line start voltage offset and an indication of a block type associated with the word line start voltage offset at the controller. In some examples, the controller stores a lowest word line start voltage offset for each block type associated with the memory device.

In some examples, the controller 425 may be configured as or otherwise support a means for communicating, from a controller to a memory device, one or more program commands to each of a plurality of memory dies of the memory device. In some examples, the memory device 430 may be configured as or otherwise support a means for performing one or more program operations at each memory die of the memory device using a respective word line start voltage based at least in part, on communicating the one or more program commands to each of the plurality of memory dies. In some examples, the memory device 430 may be configured as or otherwise support a means for communicating a lowest word line start voltage offset associated with performing the one or more program operations for each of the memory dies to the controller based at least in part on determining the lowest word line start voltage offset from the respective word line start voltages. In some examples, the memory device 430 may be configured as or otherwise support a means for performing the one or more program operations at the plurality of memory dies simultaneously. In some examples, the controller stores a lowest word line start voltage offset for each block type associated with each of the plurality of memory dies.

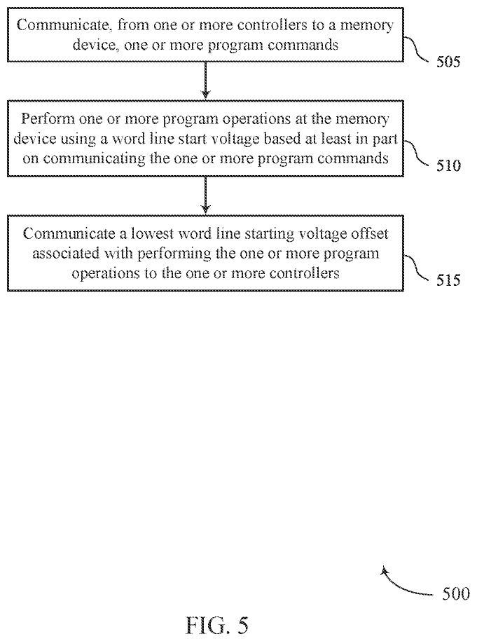

FIG. 5 illustrates a flowchart showing a method 500 that supports hybrid DWLSV in accordance with examples as disclosed herein. The operations of method 500 may be implemented by a memory system or its components as described herein. For example, the operations of method 500 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 505, the method may include communicating, from one or more controllers to one or more memory devices, one or more program commands. The operations of 505 may be performed in accordance with examples as disclosed herein. In some examples, aspects of the operations of 505 may be performed by a controller 425 as described with reference to FIG. 4.

At 510, the method may include performing one or more program operations at the memory device (e.g., one or more memory devices) using a word line start voltage based at least in part on communicating the one or more program commands. The operations of 510 may be performed in accordance with examples as disclosed herein. In some examples, aspects of the operations of 510 may be performed by a memory device 430 as described with reference to FIG. 4.

At 515, the method may include communicating a lowest word line starting voltage offset associated with performing the one or more program operations to the controller. The operations of 515 may be performed in accordance with examples as disclosed herein. In some examples, aspects of the operations of 515 may be performed by a memory device 430 as described with reference to FIG. 4.

In some examples, an apparatus as described herein may perform a method or methods, such as the method 500. The apparatus may include features, circuitry, logic, means, or instructions (e.g., a non-transitory computer-readable medium storing instructions executable by one or more processors), or any combination thereof for performing the following aspects of the present disclosure:

Aspect 1: A method, apparatus, or non-transitory computer-readable medium including operations, features, circuitry, logic, means, or instructions, or any combination thereof for communicating, from a controller (e.g., one or more controllers) to a memory device (e.g., one or more memory devices), one or more program commands; performing one or more program operations at the memory device using a word line start voltage based at least in part on communicating the one or more program commands; and communicating a lowest word line starting voltage offset associated with performing the one or more program operations to the controller.

Aspect 2: The method, apparatus, or non-transitory computer-readable medium of aspect 1, further including operations, features, circuitry, logic, means, or instructions, or any combination thereof for determining whether a voltage offset exists for a block type associated with the one or more program commands and where communicating the one or more program commands includes communicating a command indicating the voltage offset. Aspect 3: The method, apparatus, or non-transitory computer-readable medium of aspect 2, where the word line start voltage is based, at least in part, on communicating the command indicating the voltage offset. Aspect 4: The method, apparatus, or non-transitory computer-readable medium of any of aspects 2 through 3, where the word line start voltage is based, at least in part, on communicating the command indicating the voltage offset and a default voltage. Aspect 5: The method, apparatus, or non-transitory computer-readable medium of any of aspects 1 through 4, where the word line start voltage is based, at least in part, on a default voltage.

Aspect 6: The method, apparatus, or non-transitory computer-readable medium of any of aspects 1 through 5, where a plurality of block types are associated with the one or more program commands and the method, apparatuses, and non-transitory computer-readable medium further includes operations, features, circuitry, logic, means, or instructions, or any combination thereof for determining whether a voltage offset exists for each block type associated with the one or more program commands and where communicating one or more commands includes communicating a command indicating a voltage offset for each block type based at least in part on determining that the voltage offset exists for the block type. Aspect 7: The method, apparatus, or non-transitory computer-readable medium of any of aspects 1 through 6, further including operations, features, circuitry, logic, means, or instructions, or any combination thereof for storing a word line start voltage offset for a first page of a block type associated with the one or more program commands; comparing the stored word line start voltage offset to a subsequent word line start voltage offset associated with a subsequent page of the block type; and replacing the stored word line start voltage offset with the subsequent word line start voltage offset if the subsequent word line start voltage offset is less than the stored word line start voltage offset.

Aspect 8: The method, apparatus, or non-transitory computer-readable medium of aspect 7, further including operations, features, circuitry, logic, means, or instructions, or any combination thereof for repeating the comparing and the replacing, until the one or more program operations have been performed on all pages of the block type and communicating an indication that the one or more program operations are complete to the controller. Aspect 9: The method, apparatus, or non-transitory computer-readable medium of any of aspects 1 through 8, where communicating the lowest word line start voltage offset includes operations, features, circuitry, logic, means, or instructions, or any combination thereof for communicating an indication that the program operation is complete to the controller and communicating the lowest word line start voltage offset in response to receiving a command from the controller. Aspect 10: The method, apparatus, or non-transitory computer-readable medium of any of aspects 1 through 9, further including operations, features, circuitry, logic, means, or instructions, or any combination thereof for storing the lowest word line start voltage offset and an indication of a block type associated with the word line start voltage offset at the controller. Aspect 11: The method, apparatus, or non-transitory computer-readable medium of aspect 10, where the controller stores a lowest word line start voltage offset for each block type associated with the memory device.

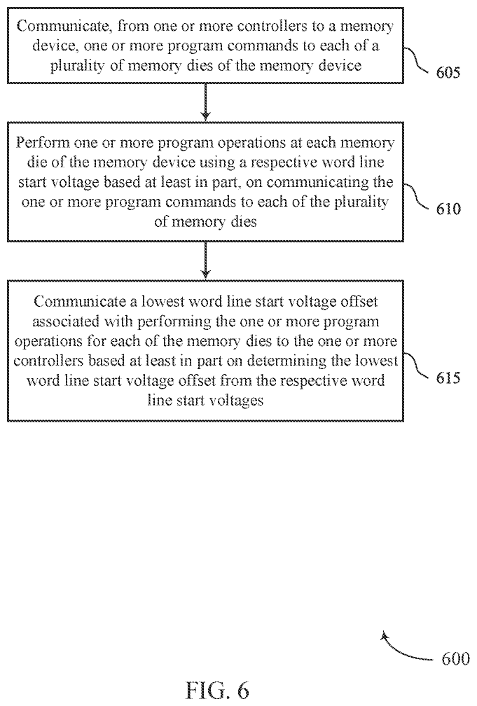

FIG. 6 illustrates a flowchart showing a method 600 that supports hybrid DWLSV in accordance with examples as disclosed herein. The operations of method 600 may be implemented by a memory system or its components as described herein. For example, the operations of method 600 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 605, the method may include communicating, from a controller (e.g., one or more controllers) to a memory device (e.g., one or more memory devices), one or more program commands to each of a plurality of memory dies of the memory device. The operations of 605 may be performed in accordance with examples as disclosed herein. In some examples, aspects of the operations of 605 may be performed by a controller 425 as described with reference to FIG. 4.

At 610, the method may include performing one or more program operations at each memory die of the memory device using a respective word line start voltage based at least in part, on communicating the one or more program commands to each of the plurality of memory dies. The operations of 610 may be performed in accordance with examples as disclosed herein. In some examples, aspects of the operations of 610 may be performed by a memory device 430 as described with reference to FIG. 4.

At 615, the method may include communicating a lowest word line start voltage offset associated with performing the one or more program operations for each of the memory dies to the controller based at least in part on determining the lowest word line start voltage offset from the respective word line start voltages. The operations of 615 may be performed in accordance with examples as disclosed herein. In some examples, aspects of the operations of 615 may be performed by a memory device 430 as described with reference to FIG. 4.

In some examples, an apparatus as described herein may perform a method or methods, such as the method 600. The apparatus may include features, circuitry, logic, means, or instructions (e.g., a non-transitory computer-readable medium storing instructions executable by one or more processors), or any combination thereof for performing the following aspects of the present disclosure:

Aspect 12: A method, apparatus, or non-transitory computer-readable medium including operations, features, circuitry, logic, means, or instructions, or any combination thereof for communicating, from a controller to a memory device, one or more program commands to each of a plurality of memory dies of the memory device; performing one or more program operations at each memory die of the memory device using a respective word line start voltage based at least in part, on communicating the one or more program commands to each of the plurality of memory dies; and communicating a lowest word line start voltage offset associated with performing the one or more program operations for each of the memory dies to the controller based at least in part on determining the lowest word line start voltage offset from the respective word line start voltages. Aspect 13: The method, apparatus, or non-transitory computer-readable medium of aspect 12, further including operations, features, circuitry, logic, means, or instructions, or any combination thereof for performing the one or more program operations at the plurality of memory dies simultaneously. Aspect 14: The method, apparatus, or non-transitory computer-readable medium of any of aspects 12 through 13, where the controller stores a lowest word line start voltage offset for each block type associated with each of the plurality of memory dies.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed and second condition or action may occur directly as a result of the previous condition or action occurring independent of whether other conditions or actions occur. In some examples, a first condition or action may be performed and second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively (e.g., in an alternative example), be performed “in direct response to” or “directly in response to” such other condition or action unless otherwise specified.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by one or more processors, firmware, or any combination thereof. If implemented in software executed by one or more processors, the functions may be stored on or transmitted over, as one or more instructions or code, a computer-readable medium. Other examples and implementations are within the scope of the disclosure and appended claims. For example, due to the nature of software, the described functions can be implemented using software executed by one or more processors, hardware, firmware, hardwiring, or combinations of any of these. Features implementing functions may also be physically located at various positions, including being distributed such that portions of functions are implemented at different physical locations.

For example, the various illustrative blocks and components described in connection with the disclosure herein may be implemented or performed with a general-purpose processor, a DSP, an ASIC, an FPGA or other programmable logic device, discrete gate or transistor logic, discrete hardware components, or any combination thereof designed to perform the functions described herein. A general-purpose processor may be a microprocessor, but in the alternative, the processor may be any processor, controller, microcontroller, or state machine. A processor may be implemented as a combination of computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

Computer-readable media includes both non-transitory computer storage media and communication media including any medium that facilitates transfer of a computer program from one place to another. A non-transitory storage medium may be any available medium that can be accessed by a general purpose or special purpose computer. By way of example, and not limitation, non-transitory computer-readable media can comprise RAM, ROM, electrically erasable programmable read-only memory (EEPROM), compact disk (CD) ROM or other optical disk storage, magnetic disk storage or other magnetic storage devices, or any other non-transitory medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, include CD, laser disc, optical disc, digital versatile disc (DVD), floppy disk, and Blu-ray disc, where disks usually reproduce data magnetically, while discs reproduce data optically with lasers. Combinations of these are also included within the scope of computer-readable media.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus, comprising:
one or more controllers associated with a memory device, wherein the one or more controllers are configured to cause the apparatus to:
communicate, from the one or more controllers to the memory device, one or more program commands;
perform one or more program operations at the memory device using a word line start voltage based at least in part on communicating the one or more program commands; and
communicate a lowest word line starting voltage offset associated with performing the one or more program operations to the one or more controllers.

2. The apparatus of claim 1, wherein the one or more controllers are further configured to cause the apparatus to:
determine whether a voltage offset exists for a block type associated with the one or more program commands,
wherein communicating the one or more program commands includes communicating a command indicating the voltage offset.

3. The apparatus of claim 2, wherein the word line start voltage is based, at least in part, on communicating the command indicating the voltage offset.

4. The apparatus of claim 2, wherein the word line start voltage is based, at least in part, on communicating the command indicating the voltage offset and a default voltage.

5. The apparatus of claim 1, wherein the word line start voltage is based, at least in part, on a default voltage.

6. The apparatus of claim 1, wherein a plurality of block types are associated with the one or more program commands, and the one or more controllers are further configured to cause the apparatus to:
determine whether a voltage offset exists for each block type associated with the one or more program commands,
wherein communicate one or more commands includes communicating a command indicating a voltage offset for each block type based at least in part on determining that the voltage offset exists for the block type.

7. The apparatus of claim 1, wherein the one or more controllers are further configured to cause the apparatus to:
store a word line start voltage offset for a first page of a block type associated with the one or more program commands;
compare the stored word line start voltage offset to a subsequent word line start voltage offset associated with a subsequent page of the block type; and
replace the stored word line start voltage offset with the subsequent word line start voltage offset if the subsequent word line start voltage offset is less than the stored word line start voltage offset.

8. The apparatus of claim 7, wherein the one or more controllers are further configured to cause the apparatus to:
repeat the comparing and the replacing, until the one or more program operations have been performed on all pages of the block type; and
communicate an indication that the one or more program operations are complete to the one or more controllers.

9. The apparatus of claim 1, wherein communicating the lowest word line start voltage offset is configured to cause the apparatus to:
communicate an indication that the program operation is complete to the one or more controllers; and
communicate the lowest word line start voltage offset in response to receiving a command from the one or more controllers.

10. The apparatus of claim 1, wherein the one or more controllers are further configured to cause the apparatus to:
store the lowest word line start voltage offset and an indication of a block type associated with the word line start voltage offset at the one or more controllers.

11. The apparatus of claim 10, wherein the one or more controllers stores a lowest word line start voltage offset for each block type associated with the memory device.

12. A non-transitory computer-readable medium storing code, the code comprising instructions executable by one or more processors to:
communicate, from one or more controllers to a memory device, one or more program commands;
perform one or more program operations at the memory device using a word line start voltage based at least in part on communicating the one or more program commands; and
communicate a lowest word line starting voltage offset associated with performing the one or more program operations to the one or more controllers.

13. The non-transitory computer-readable medium of claim 12, wherein the instructions are further executable by the one or more processors to:
determine whether a voltage offset exists for a block type associated with the one or more program commands,
wherein communicate the one or more program commands includes communicating a command indicating the voltage offset.

14. The non-transitory computer-readable medium of claim 13, wherein the word line start voltage is based, at least in part, on communicating the command indicating the voltage offset.

15. The non-transitory computer-readable medium of claim 13, wherein the word line start voltage is based, at least in part, on communicating the command indicating the voltage offset and a default voltage.

16. The non-transitory computer-readable medium of claim 12, wherein the word line start voltage is based, at least in part, on a default voltage.

17. The non-transitory computer-readable medium of claim 12, wherein a plurality of block types are associated with the one or more program commands, and the instructions are further executable by the one or more processors to:
determine whether a voltage offset exists for each block type associated with the one or more program commands,
wherein communicate one or more commands includes communicating a command indicating a voltage offset for each block type based at least in part on determining that the voltage offset exists for the block type.

18. The non-transitory computer-readable medium of claim 12, wherein the instructions are further executable by the one or more processors to:
store a word line start voltage offset for a first page of a block type associated with the one or more program commands;
compare the stored word line start voltage offset to a subsequent word line start voltage offset associated with a subsequent page of the block type; and
replace the stored word line start voltage offset with the subsequent word line start voltage offset if the subsequent word line start voltage offset is less than the stored word line start voltage offset.

19. The non-transitory computer-readable medium of claim 18, wherein the instructions are further executable by the one or more processors to:
repeat the comparing and the replacing, until the one or more program operations have been performed on all pages of the block type; and
communicate an indication that the one or more program operations are complete to the one or more controllers.

20. A method, comprising:
communicating, from a controller to a memory device, one or more program commands;
performing one or more program operations at the memory device using a word line start voltage based at least in part on communicating the one or more program commands; and
communicating a lowest word line starting voltage offset associated with performing the one or more program operations to the controller.
